(19) United States
(12) Patent Application Publication
(10) Pub. No.: US 2022/0140509 A1
(43) Pub. Date: May 5, 2022

(54) BIPOLAR ELECTRICAL CONNECTOR WITH DOUBLE MECHANICAL CLAMPING ON CONDUCTIVE TAPE

(71) Applicant: Carlos SAIZ, Challes les Eaux (FR)

(72) Inventor: Carlos SAIZ, Challes les Eaux (FR)

(21) Appl. No.: 17/429,949

(22) PCT Filed: Feb. 6, 2020
(86) PCT No.: PCT/FR2020/050210

§ 371 Date: Aug. 11, 2021

(30) Foreign Application Priority Data
Feb. 11, 2019 (FR) 1901356

(51) Int. Cl. H01R 12/65; H01L 31/02; H01M 10/46; A01M 29/28; A01G 13/10

(52) U.S. Cl. CPC H01R 12/65; H01L 31/02008; H01M 10/465; A01M 2200/011; A01G 13/105; H01M 2220/30; A01M 29/28

(57) ABSTRACT

Disclosed is an electrical repellent device comprising an electric generator (50) connected via its two terminals to a conductive composite tape (3) around an object to be protected and connecting the electric generator (50) and the conductive composite tape (3), the connector being characterized in that it comprises: support (1) made from metal material or insulating polymer; and at least two rods (15) mounted on the support (1) and each comprising, on their outer surface, at least one conductive element (20); and a pressure component keeping the at least one conductive element (20) in contact with at least one conductive strip (31) or the composite tape (3); and two connection terminals configured to apply the potential difference that exists between the two terminals of the electric generator (50) and the conductive elements.

### FIELD OF INVENTION

This invention relates to special electrical connectors and, more specifically, to those adapted to conductive composite tapes.

The electrical connectors which are the subject-matter of the invention are particularly suited to the field of repellent electrical belts, most particularly to those intended for the protection of fruit trees against the invasion of ants.

### PRIOR ART

There are many solutions intended to protect plantations and constructions against the invasion of particularly harmful insects and that more generally target the arthropods.

Among these solutions, devices are known to comprise a flexible longitudinal device that may act as a barrier by completely conforming to the surfaces used by the insects to reach the points of interest they like. Generally, these devices incorporate electrically conductive elements that insects tread upon during their passage through said devices.

These conductive elements are distributed over the longitudinal device and powered by an electrical supply so that the insects are struck down in the justified case of pests or simply shocked in the case of ants which are not considered to be pests. This occurs when the insects are subjected to both the positive potential and the negative potential from the electrical supply, for example, when the insects tread upon the longitudinal device and thus form a conducting bridge for the current.

American patent application US 2006/0143974 describes an electrical device for protecting constructions from the invasion of termites, in which the insects are electrocuted by passing over conductive wires contained in a flexible longitudinal device. On the other hand, the device to connect the source of the current to the flexible longitudinal device is not described in this document. Therefore, it seems that this device may leave points for possible passage of the insects, particularly through the connector, which they can cross without risk of electrocution. This, therefore, weakens the system because most insects discover this point of passage through the device by successive trial and error.

German patent application DE 102016002094 also describes an electrical repellent device but does not describe the nature and the embodiment of the electrical connector. On the other hand, FIGS. 3a, 3b, and 11 represent the electrical connector as a basic element, the design of which does not seem to prevent the passage of pests through it. For example, the connector illustrated by FIG. 11 suggests that a colony of ants would have very quickly found the passage from the top or the sides of this compartment and thus cross the barrier.

Therefore, it is not easy to find a connector that, once subjected to bad weather, can ensure both a flawless electrical connection and which itself represents a barrier against insects that is at least as effective as the longitudinal device itself.

French patent FR 2,842,705 proposes a connector comprising pins that make it possible to ensure both the electrical connection and the mechanical clamping of said longitudinal device around an object to be protected. To do this, this connector uses insulating pins housed between two conductive tapes of said longitudinal device. To fit into the small spaces separating two electrically conductive tapes, the diameter of the insulating pins must be very small, on the order of a millimeter. Thus, tightening said longitudinal device by this system of pins is random, and the connection is made difficult or even impossible to implement.

### DISCLOSURE OF THE INVENTION

Therefore, the technical problem which the invention aims to solve is to propose an electrical device provided with a connector capable of maintaining a conductive composite tape around an object to be protected; this composite tape having an electrical connection to an electrical supply, and finally, to create of an impassable barrier against the insects.

This invention proposes to solve this technical problem with an electrical repellent device comprising an electrical generator connected by its two terminals to a composite tape including conductive tracks, and a connector that ensures mechanical clamping of the conductive composite tape around an object to be protected on the one hand, and on the other hand, a connection between the electric generator and the conductive tracks of the conductive composite tape.

More precisely, said connector is characterized in that it advantageously comprises:
a support extending across the width of the tape; and
at least two rods mounted on the support and each comprising at least one conductive element on their outer surface; and
a pressure component to keep said at least one conductive element in contact with at least one conductive track of said composite tape; and
two connection terminals configured to apply the potential difference between the electric generator's two terminals and said conductive elements.

According to a first embodiment of the invention, the pressure component is a compressible material, in particular, a foam mounted on the mounting box opposite the two rods.

According to a second embodiment of the invention, the pressure component is an eccentric carrying each of the two rods.

The composite tape may be created in various ways.

In an advantageous embodiment, the composite tape is a flexible film comprising parallel metal tracks, that is to say, separated by an insulating zone. These tracks may be obtained in different ways, by deposition, gluing, co-laminating, or the like. Preferably, the tracks may be created from a continuous metallic layer present on the flexible film, this metallic layer being removed by chemical, mechanical or thermal etching in the areas of separation between tracks. This flexible film may be replaced by a textile coated on one side upon which the conductive tracks are formed.

In another embodiment, the conductive composite tape is a textile tape inside of which are woven conductive strips that form the conductive tracks, separated by the insulating material that forms the fabric threads parallel to said tracks.

In this case, the conductive strips may be formed by stainless steel strips.

Advantageously, the conductive strips are insulated from each other and are each in contact with at least one of said conductive elements.

Advantageously, the conductive elements of the connector are advantageously stainless metal spacers threaded around said connection terminals, and alternatively, with the insulating bushings.

Advantageously, each rod comprises an axis powered by one of the two terminals of said generator.

Advantageously, the electric generator is a photovoltaic cell, for example, made of amorphous silicon, delivering an electric voltage of between 8 volts and 17 volts. In practice, the provision may advantageously be made to protect the photovoltaic cell by covering it with a transparent plate.

In the case of tree ants whose activity is diurnal, it is not necessary to have a buffer battery for the night.

In another embodiment, the electric generator delivers electric pulses through a high-efficiency oscillator adjustable in intensity and/or frequency by the user.

Advantageously, the device is powered by direct current by a circuit comprising a battery which may be used alone or coupled to a photovoltaic cell.

In one particular embodiment, the device may include a protective screen extending around the conductive tape while being distant from the latter. Provision may be made to use a spacer interposed between the upper edge of the conductive tape and the protective screen to keep said screen at a distance from the tape. In this way, the tape is protected from splashing water in the event of rain, and the associated risks of electrolysis, with the consequences in terms of energy autonomy and premature aging.

### SUMMARY DESCRIPTION OF FIGURES

The manner of carrying out the invention, as well as the advantages which result therefrom, will emerge clearly from the description of the embodiments which follow, in support of the appended figures in which:

FIG. 1 is a top view of the electrical connector according to a first embodiment of the invention; and

FIG. 2 is a cross-sectional view of the electrical connector along the plane I-I′ of FIG. 1; and

FIG. 3 is a front view of the electrical connector according to a second embodiment of the invention; and.

FIG. 4 is a cross-sectional view of the electrical connector along the plane II-II′ of FIG. 3.

FIG. 5 is a summary perspective view of the repellent device of the invention in a configuration for use.

FIG. 6 is a cross-sectional view VI-VI′ of FIG. 5.

### DETAILED DESCRIPTION

The invention relates to an electrical repellent device comprising an electrical generator 50 connected by its two terminals 51, 52 to a conductive composite tape 3, and a connector ensuring, on the one hand, mechanical clamping of the conductive composite tape 3 around an object to be protected and on the other hand, a connection between the electric generator 50 and the conductive composite tape 3.

The object to be protected from an invasion of insects such as ants is surrounded by a conductive composite tape. This conductive composite tape is composed of an insulating core 30 to which are secured several parallel conductive strips 31 of the same width.

Advantageously, and as visible in FIG. 2, tape 3 has an outer surface Se. According to one preferred way of carrying out the invention, the core 30 of this tape 3 is composed of a polyester film from 50 μm to 150 μm thick, typically 75 μm thick, comprising on at least one of its surfaces the conductive strips 31, so that the outer surface Se is composed of the upper surface of said polyester film 30 and the upper surface of said conductive strips 31.

In practice, these conductive strips may be made from an aluminum layer either deposited by PVD or co-laminated onto the film 30. The aluminum layer is ultra-pure and has a thickness between 100 nm and 12 μm, ideally close to 9 μm. The electrical pattern on the aluminum layer is obtained either by laser engraving or by chemical engraving. For example, it is possible to proceed by photosensitizing a protective varnish deposited upon the aluminum layer, then dissolving the sensitized varnish and dissolving the unwanted aluminum in a lukewarm bath of a sodium hydroxide dilution.

The outer surface Se of said tape 3 is located towards the outside of the object to be protected so as to be accessible to the passage of insects, which, for example, would climb upon this object.

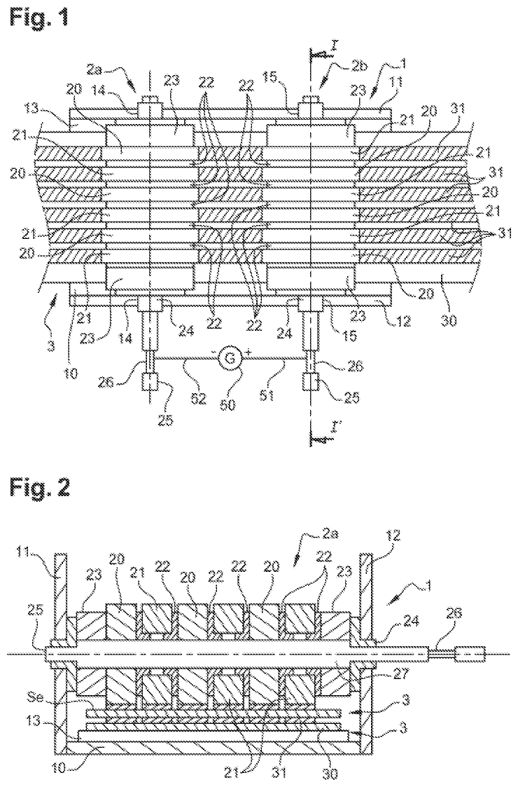

According to a first embodiment of the invention illustrated by FIG. 1, the connector comprises a support 1 composed of a support base 10 and two identical wings 11, 12, attached by their base to the support base 10. The support base 10 and the two wings 11, 12 have a parallelepipedal profile and are advantageously made of a stainless metal or of an electrically insulating plastic material. Advantageously, support 1 is composed of rigid sheets of metal material such as stainless steel, these sheets having a thickness between 0.6 mm and 2 mm, preferably 1 mm.

The support may also be made of a plastic material, such as polyvinyl chloride (PVC) or polymethyl methacrylate (PMMA). These sheets of plastic material have a thickness of between 3 and 10 mm, advantageously close to 5 mm.

Each of the two wings 11, 12 is pierced with two through-holes 14, 15. Advantageously, the two holes 14, 15 are located on a straight line parallel to the longer side of said wings 11, 12.

The holes 14 of each of the two wings 11, 12 face each other and thus share the same axis. Likewise, the holes 15 of each of the two wings 11, 12 face each other and share an identical axis.

The axis defined by the alignment of the holes 14 carries a first rod in the form of a connector cylinder 2a. Likewise, the axis defined by the alignment of the holes 15 carries a second rod in the form of a connector cylinder 2b.

Each cylinder 2a, 2b is carried at its center by a cylindrical shaft 25, advantageously made from stainless steel. This shaft 25 is composed of a succession of several cylindrical portions sharing the same shaft, collinear with the axis of the holes 14 for cylinder 2a and of the holes 15 for cylinder 2b.

In particular, each shaft 25 comprises, at one of its ends, a connection section 26 of reduced diameter relative to the general diameter of the pin, defined between two shoulders. The connection section 26 advantageously makes it possible to apply a difference in potential to each of the shafts 25 that stem from a generator 50 by means of connecting wires 51, 52. Each of these connecting wires 51, 52 is extended by a clip that reversibly surrounds each of the shafts 25. This clip may take the form of a circular spring, the ends of which, on the one hand, make it possible to ensure a force that counteracts the spring effect and thus makes it possible to position the spring on shaft 25. On the other hand, this end may be designed to receive a connection terminal present at the end of the connecting wire 51, 52.

Each of the connector cylinders is rotatably mounted relative to connector 1 by means of two insulating bearings 24 placed at each end of the shafts 25. These bearings 24 are made of plastic, advantageously of polyamide (PA 6), the inside diameter of which matches the outside diameter of said shafts 25. Advantageously, bearings 24 make it possible to electrically isolate the wings 11, 12 from each of the shafts 25 and thus isolate the shafts 25 from one another.

A longitudinal portion 27 extends between the two bearings 24, defined as the longest part of this shaft 25. This longitudinal portion 27 has the largest diameter of all the portions making up shaft 25.

Three active spacers 20 and three passive spacers 21 are mounted on each longitudinal portion 27. The active 20 and passive 21 spacers are disks of the same thickness and of the same external diameter, pierced with a hole in their center, thus defining an internal diameter of each of these spacers.

Advantageously, the active 20 and passive 21 spacers are obtained from stainless steel, providing them with increased resistance against the meteorological hazards to which they will be subjected.

It should be noted that the internal diameter of the active spacers 20 is narrower than that of the passive spacers 21.

Indeed, alternating is created between each active 20 and passive 21 spacers on each shaft 25. The active spacers 20 are mounted directly onto shaft 25 so as to bring their inner diameter into contact with the outer surface of the shaft. Consequently, this advantageously makes it possible to transmit the electric potential to which each of the shafts 25 is subjected to the active spacers 20.

On the contrary, the passive spacers 21 are mounted on shaft 25 by means of insulating bushings 22. Each insulating bushing 22, which is advantageously electrically insulating and obtained from PA6, is composed of a disc from which a cylindrical extrusion extends from its center. The assembly is pierced with a central orifice, the diameter of which is substantially equal to the internal diameter of the active spacers 20.

The molding of these insulating bushings 22 has a length less than half the thickness of the passive spacers 21, and their outer diameter is substantially equal to the inner diameter of these spacers.

The thickness of each of the insulating bushing discs 22 is between 0.5 and 2 mm, being advantageously close to 1 mm, and their outside diameter is less than the diameter of the active 20 and passive 21 spacers.

Two insulating bushings 22 are mounted head to tail in the hole of each of the passive spacers 21. Each of the passive assemblies thus formed is then mounted on shaft 25, and alternatively, with the active spacers 20, so as to form the cylinders 2a, 2b. Thus, the distance between the active 20 and passive 21 spacers is constant.

Two centering spacers 23 are mounted on either side of the alternating assembly defined by the active 20 and passive 21 spacers. These centering spacers 23 are advantageously obtained from PA6. Their outer diameter is less than the outer diameter of the active 20 and passive 21 spacers. A hole drilled into their center defines the internal diameter of the insulating spacers 23, which is advantageously substantially equal to the external diameter of each shaft 25.

These centering spacers 23 make it possible to center the alternating assembly between the two wings 11, 12.

It should be noted that within the meaning of the invention, the alternating assemblies carried by the connector cylinders 2a, 2b have an opposite pattern, that is to say, that the opposing spacers are different from each other. This advantageously allows a conductive strip 31 of said longitudinal composite strip 3 to be in contact with a single active spacer 20 and a single passive spacer 21.

Indeed, the longitudinal composite tape 3 is inserted within the connector under the conductive rods 2a, 2b and rests upon a deformable foam 13 covering the support base 10. The longitudinal composite tape overlaps at the connector on an upper and lower fold.

The deformable foam 13, composed of polymeric material, has a thickness of between 5 and 15 mm, advantageously close to 10 mm. It has the ability to be able to be reversibly deformed; that is to say, it has elasticity. It acts as a clamping means, advantageously allowing the longitudinal composite tape 3 to be compressed against the conductive rods so as to ensure electrical conduction between the active spacers 20 and the conductive strips 31, and also makes it possible to maintain the mechanical clamping of said conductive composite tape 3 around the object to be protected.

Thus, the outer surface Se is kept compressed against the two conductive cylinders 2a, 2b by the deformable foam 13, such that each conductive strip 31 is in contact with an active spacer 20 and a passive spacer 21, respectively.

In this way, each conductive strip 31 is subjected to a single potential. Thus, an insect that comes into simultaneous contact with two adjacent conductive strips 31, such as, for example, when they are stepped upon, creates an electrical bridge through its body. The electric current passes through its body, causing it to be electrocuted, thus ensuring the protection of the object to be protected.

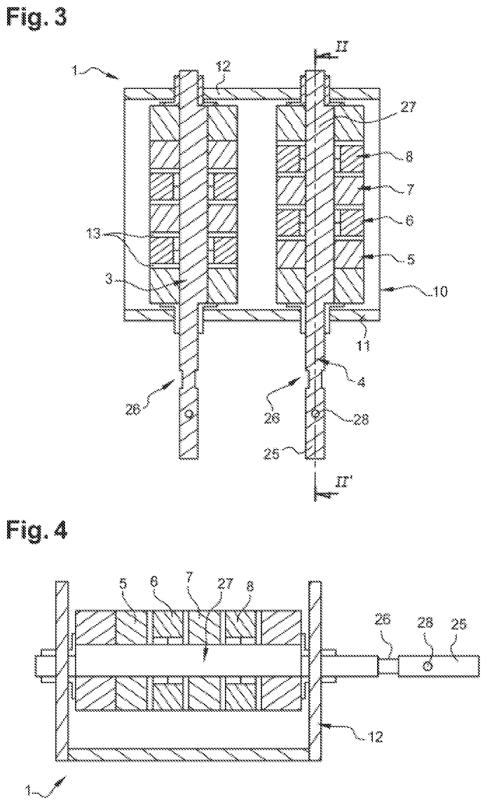

According to a second embodiment of the invention, shown in FIGS. 3 and 4, the pressure means is composed of an eccentric.

This eccentric is formed by an offset of the longitudinal portion's shaft 27. Indeed, the shaft of the longitudinal portion 27 is parallel to the shaft of shaft 25, having an offset value of between 5 and 10 mm, advantageously close to 7 mm. Thus, when shaft 25 pivots within the bearings 24, the longitudinal portion 27 does not pivot along its axis of revolution, thus defining an eccentric movement.

By means of an orifice 28 drilled along an axis perpendicular to shaft 25, near shoulder 26, the user may thus rotate the shaft 25, thereby allowing conductive composite tape 3 to be crushed through the eccentric defined by longitudinal portion 27.

The electrical connector according to the invention, is particularly suitable for outdoor use. Indeed, the choice of materials, such as stainless steel and PA6, makes it highly resistant to natural aggressions such as corrosion and ultraviolet rays.

Also, the fact that the cylinders 2a, 2b are exposed to the exterior of the connector advantageously makes the insect repellent device impassable. Indeed, the device does not present any discontinuity in the protection that it confers around the object to be protected.

The generator 50 is advantageously a battery, for example, a battery of the 12V MN21 or 12V MN27 type. Advantageously, this battery is connected to a photovoltaic panel, making it possible to keep it charged. For example, the photovoltaic panel marketed by SOLEMS under the reference 13/55/32 may be used. Advantageously, a charger connected to power also makes it possible to recharge the battery when it is discharged.

Advantageously, generator 50 delivers a direct current in the form of electrical pulses. An electronic device also allows a user to modulate these pulses in intensity and/or in frequency. It is also possible to design the generator to have several modules to generate potential differences of several distinct amplitudes, for example, increasing in the direction of the insects' progression. In this way, among the variety of insects that climb trees, the most sensitive insects are repelled from their first step without being killed, while the most robust, which would have crossed the first voltage threshold, would be driven back by the second threshold or the third.

In practice, the programming of the generator can make it possible to make the device active during certain time slots, for example, so as to let certain nocturnal pollinating insects stay overnight.

For some applications, it is also possible to render the barrier lethal with a sufficiently high voltage in accordance with the pest in order to at least partially eradicate the colony. To do this, the photovoltaic cell may be adapted, or several standard photovoltaic cells may be put into series to obtain the lethal voltage.

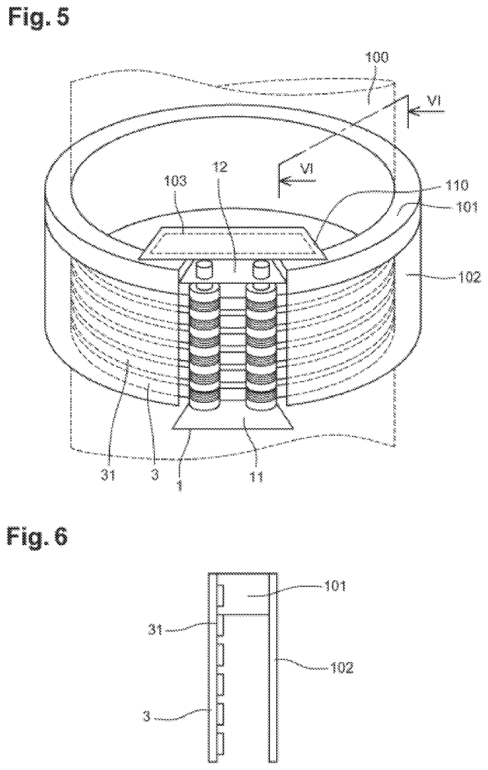

According to another aspect of the invention, it may be useful to protect the tape from the risks of oxidation linked to the fact that the device is exposed to inclement weather, and in particular to rain. Thus, as illustrated in FIGS. 5 and 6, tape 3 is wound onto itself in a cylindrical configuration and held tight on branch 100 by connector 1. In its upper part, tape 3 comprises a bead 101 of waterproof foam, such as ethylenepropylene-dienemonomer (or EPDM) or even silicone foam, which may be glued by a double-faced adhesive strip, for example. This bead 101 receives a skirt 102 on its external face formed of an advantageously transparent film, typically based on polyester. The thickness of the foam bead is chosen to prevent a pest from climbing onto the skirt 102 and thus avoid being in contact with the conductive tape 3. This skirt 102 extends downward to the height of the bottom edge of the conductive tape. The skirt 102 extends over the entire periphery of the device with the exception of the area where connector 1 is implanted and limits the risks of rain reaching the conductive tape 3 or of water flowing down the branch receiving the device from reaching the conductive tracks 31.

Additionally, the device is equipped with a protective plate 110 placed above connector 1, the generator, and/or the photovoltaic cell 103. This plate 110 prevents water from reaching and stagnating on the photovoltaic cell, with the risk of damaging the latter. This plate 110 can advantageously be made of transparent polymer to allow the light energy necessary for the correct operation of this cell 103 to pass through. Materials with water-repellent properties, such as fluorinated materials, are recommended for this function.

It is well understood from all of the above that the electrical connector has the fundamental ability to oppose an electrical barrier as effective as that provided by the conductive composite tape 3 that it powers.

It is easy to understand that the device described above with identical conductive tracks may be modified to be adapted to other configurations. Thus, special conductive composite tapes may be designed to have multiple groups of conductive tracks. Indeed, if, for example, one wishes to block the route to two groups of ants of very different sizes, it will be necessary to produce on the same conductive composite tape two related series of electrical barrier tracks.

For example, in the south of France, we commonly find ants of the Messor barbarus family whose size varies from 4 mm to 12 mm, which coexist with Monomorium carbonarium ants whose size varies from 1.4 mm to 1.8 mm.

For a total shutdown efficiency, while being certain that the ants of each type are always electrocuted, at least three isolated 6 mm tracks of 1 mm will be provided for the Messor barbarusants, while for the smaller Monomorium carbonarium, 4 isolated tracks of 3 mm of 1 mm are provided. This particular composite tape thus has the ability to be adapted to block insects of different sizes. The electrical connector described above is perfectly suited to this type of multi-pitch multitrack conductive composite tape.

1. Electrical repellent device comprising an electric generator (50) connected by its two terminals to a conductive composite tape (3) including conductive tracks (31), and a connector ensuring, on the one hand, a mechanical clamping of the conductive composite tape (3) around an object to be protected and on the other hand a connection between the electric generator (50) and the conductive composite tape (3), said connector being characterized in that it comprises:
a support (1) extending across the width of the tape; and
at least two rods (2a, 2b) mounted on the support and each comprising at least one conductive element (20) on their outer surface; and
a pressure component keeping said at least one conductive element in contact with at least one conductive track (31) of said composite tape (3); and
two connection terminals (51, 52) configured to apply the difference in potential existing between the two terminals of the electric generator (50) and said conductive elements (20).

2. Device according to claim 1 characterized in that the pressure component is a compressible material (13) mounted on the mounting box opposite the two rods (2a, 2b).

3. Device according to claim 1 characterized in that the pressure component is an eccentric carrying each of the two rods (2a, 2b).

4. Device according to claim 1, characterized in that the conductive elements (20, 5, 7) are metal spacers threaded around said connection terminals, and alternatively with insulating bushings (22, 6, 8).

5. Device according to claim 1, characterized in that the conductive composite tape (3) is a flexible film (30) with at least one side covered with a metal layer on which separate conductive tracks are formed.

6. Device according to claim 1, characterized in that the conductive composite tape (3) is a textile in which conductive strips and insulating wires that separate said tracks are woven.

7. Device according to claim 1, characterized in that the conductive tracks (31) are stainless steel strips.

8. Device according to claim 1, characterized in that each rod (2a, 2b) comprises a shaft (25) powered by one of the two terminals of said generator (50).

9. Device according to claim 1, characterized in that it is powered by direct current through a photovoltaic cell, preferably of amorphous silicon.

10. Device according to claim 9, characterized in that it includes a transparent plate covering the photovoltaic cell.

11. Device according to claim 1, characterized in that the electric generator (50) delivers electric pulses by a high-efficiency oscillator adjustable in intensity and/or frequency by the user.

12. Device according to claim 1, characterized in that it is powered by direct current through a circuit comprising a battery.

13. Device according to claim 1, characterized in that it includes a protective screen extending around the conductive tape while being distant from the latter.

14. Device according to claim 13, characterized in that it includes a spacer interposed between the upper edge of the conductive tape and the protective screen in order to keep said screen at a distance from the tape.
